(19) United States
(12) Patent Application Publication
(10) Pub. No.: US 2012/0192916 A1
(43) Pub. Date: Aug. 2, 2012

(54) Photovoltaic Fiber, Photovoltaic Cell Module Using The Same, And Method Of Manufacturing The Same

(75) Inventors: Xianyu WENXU, Suwon-Si (KR); Yeon-Hee KIM, Songpa-gu (KR); Woo Young YANG, Gyeonggi-do (KR)

(73) Assignees: SAMSUNG SDI CO., LTD., Yongin-Si (KR); SAMSUNG ELECTRONICS CO., LTD., Suwon-sI (KR)

(21) Appl. No.: 13/286,609

(22) Filed: Nov. 1, 2011

(30) Foreign Application Priority Data
Jan. 31, 2011 (KR) 10-2011-0009738
Aug. 11, 2011 (KR) 10-2011-0080332

(51) Int. Cl. H01L 31/045; H01L 31/18; H01L 31/02

(52) U.S. Cl. 136/245; 136/256; 438/98; 257/E31.124

(57) ABSTRACT

A photovoltaic fiber may include a first electrode surrounding a base fiber, a photoactive layer surrounding the first electrode and having a photovoltaic junction positioned in a radial direction. The photovoltaic fiber may also include a second electrode surrounding the photoactive layer is provided.

### CROSS-REFERENCE TO RELATED APPLICATION

This application claims priority under 35 USC §119 to Korean Patent Application No. 10-2011-0009738 filed in the Korean Intellectual Property Office (KIPO) on JAN. 31, 2011 and Korean Patent Application No. 10-2011-0080332 filed in the Korean Intellectual Property Office (KIPO) on AUG. 11, 2011, the entire contents of which are incorporated herein by reference.

### BACKGROUND

1. Field

A photovoltaic fiber, a photovoltaic cell module using the same, and a method of manufacturing the same are provided.

2. Description of the Related Art

A photovoltaic cell is a device that converts light energy into electrical energy and stores the electrical energy. Since the photovoltaic cell may solve the depletion of fossil fuels and environmental pollution, studies for developing a highly efficient and inexpensive photovoltaic cell are actively progressing.

Particularly, since a bulk crystalline silicon solar cell (bulk c-Si solar cell) has higher efficiency but is easily damaged, it may be difficult to manufacture a mobile solar cell. Furthermore, a thin film solar cell such as an amorphous silicon PIN solar cell (a-Si PIN solar cell), a DIGS (CuInGaSe₂) solar cell, and the like that is manufactured on a flexible substrate has lower efficiency and is harder to manufacture.

### SUMMARY

According to at least one example embodiment, a photovoltaic fiber is manufactured by coating a material for forming an electrode and a photoactive layer on a base fiber The base fiber may include a glass fiber, a plastic fiber, a polymer fiber, a carbon fiber, and the like. The photovoltaic fiber may include a first electrode surrounding the base fiber. Also, the photovoltaic fiber may include a photoactive layer surrounding the first electrode and having a photovoltaic junction positioned in a radial direction. Furthermore, the photovoltaic fiber may include a second electrode surrounding the photoactive layer.

The material used for the photoactive layer may include amorphous silicon (a-Si), multi-crystalline silicon (inc-Si), nanocrystalline silicon (nc-Si), CIGS (CuInGaSe2), a compound semiconductor such as CdTe, an organic compound, a material having a multi-junction, and the like. The amorphous silicon may include hydrogenated amorphous silicon (a-Si:H), the multi-crystalline silicon may include hydrogenated multi-crystalline silicon (mc-Si:H), and the nanocrystalline silicon may include hydrogenated nanocrystalline silicon (nc-Si:H).

According to one example embodiment, the photovoltaic fabric includes woven photovoltaic fibers.

According to one example embodiment, the photovoltaic cell module includes a photovoltaic cell device. The photovoltaic cell module may further include at least one of a storage unit and a switching device. A conductive fiber may be used instead of the switching device.

The photovoltaic cell device may be configured to convert light energy into electrical energy, and the photovoltaic cell device may include woven photovoltaic fibers. The storage unit may be configured to store converted electrical energy, and storage unit may include at least one of woven capacitor fibers, a capacitor, and a battery. The switching device may be configured to control at least one of the converted electrical energy and stored electrical energy, and the switching device may include at least one of woven switching fibers and a thin film transistor.

Accordingly to an example embodiment a photovoltaic cell module may include a photovoltaic cell device comprising woven photovoltaic fibers. The photovoltaic cell device may include a plurality of isolation blocks and an isolation region. The isolation region may be positioned at the circumference of an isolation block. A base fiber may be exposed in the isolation region. Furthermore, the isolation block includes a first photovoltaic fiber extending in a first direction and a second photovoltaic fiber extending in a, second direction. More so, the first direction and the second direction may be different from each other.

According to one example embodiment, the photovoltaic fiber may be manufactured by a roll-to-roll process without using a large area deposition apparatus.

A photovoltaic fiber may be highly efficient, light, flexible, and easy to manufacture as a fabric. The photovoltaic fiber may be used as a power supply of wearable mobile electronics, and a photovoltaic cell module may be manufactured with a larger area without using a large area deposition apparatus. Accordingly, manufacturing costs may also be cheaper.

### BRIEF DESCRIPTION OF THE DRAWINGS

The above and other features and advantages will become more apparent by describing in detail example embodiments thereof with reference to the attached drawings.

FIG. 1 to FIG. 12 schematically show a process of manufacturing a photovoltaic fiber according to an example embodiment.

FIG. 13 to FIG. 14 schematically show woven photovoltaic fibers according to an example embodiment.

FIG. 15 is a cross-sectional view cutting along the line XV-XV of FIG. 14.

FIG. 16 schematically shows a plurality of photovoltaic cell blocks connected in series.

FIG. 17 schematically shows a plurality of photovoltaic cell blocks connected in parallel.

FIG. 18 schematically shows a plurality of photovoltaic cell units connected in series in one photovoltaic cell block.

FIG. 19 schematically shows a connection structure of two electrodes positioned at different layers.

FIG. 20 schematically shows a plurality of photovoltaic cell units connected in parallel in one photovoltaic cell block.

FIG. 21 schematically shows a photovoltaic cell module according to an example embodiment.

FIG. 22 schematically shows a photovoltaic cell module according to an example embodiment.

FIG. 23 schematically shows a photovoltaic cell module according to an example embodiment.

FIG. 24 schematically shows a photovoltaic cell module according to an example embodiment.

FIG. 25 schematically shows a switching unit according to an example embodiment.

FIG. 26 and FIG. 27 schematically show a switching unit according to an example embodiment.

FIG. 28 schematically shows a storage unit according to an example embodiment.

FIG. 29 is a block diagram of a photovoltaic cell module according to an example embodiment.

FIG. 30 is a block diagram of a photovoltaic cell module according to an example embodiment.

### DETAILED DESCRIPTION

Various example embodiments will be described more fully hereinafter with reference to the accompanying drawings, in which some example embodiments are shown. At least one example embodiment may, however, be embodied in many different forms and should not be construed as limited to the example embodiments set forth herein. Rather, these example embodiments are provided so that this disclosure will be thorough and complete, and will fully convey the scope of at least one example embodiment to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of an example embodiment.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of an example embodiment. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of an example embodiment.

Unless otherwise defined, all terms (including technical and scientific terms) used herein have the same meaning as commonly understood by one of ordinary skill in the art to which an example embodiment belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A photovoltaic fiber according to at least one example embodiment is manufactured by coating a material for forming an electrode and a photoactive layer on a base fiber instead of a flat substrate. Furthermore, an example embodiment illustrates the photoactive layer forming a PIN junction or a PN junction in a radial direction. Further, if necessary, at least one of an electrode material, an insulating material, and the like may be coated on the photovoltaic fiber.

The photovoltaic layer may surround a first electrode to create a photovoltaic junction. The photovoltaic junction may be formed by a semiconductor or any junction of different materials that act as an electric cell if exposed to light, or any other faun of radiant energy. More so, the photovoltaic junction may induce a voltage difference between current-carrying electrodes connected to the semiconductor, different materials or any other materials that exhibit the photovoltaic effect.

The material used for the photoactive layer may include a compound semiconductor such as amorphous silicon, multi-crystalline silicon, nanocrystalline silicon, CIGS, a compound semiconductor such as CdTe and the like, an organic compound, a material having a multi junction and the like, etc. The amorphous silicon may include hydrogenated amorphous silicon, the multi-crystalline silicon may include hydrogenated multi-crystalline silicon, and the nanocrystalline silicon may include hydrogenated nanocrystalline silicon.

The electrode material may include a transparent conductive material such as ITO, AZO, and the like, an opaque conductive material, a carbon nanotube (CNT) material, a graphene material, or a combination thereof. The carbon nanotube and graphene materials have excellent flexibility.

The insulating material may include an organic insulating material, or an inorganic insulating material such as SiOx, SiNx, and the like.

The base fiber may include a glass fiber, a plastic fiber, a polymer fiber, a carbon fiber, and the like. The base fiber may be flexible and does not cause loss of entered light, and the base fiber may be manufactured with a diameter of several micrometers to dozens of micrometers. The cost to form the base fiber may be reduced by using a lower price material such as a glass fiber, a polymer fiber, and the like. Further, unlike a flat substrate or a wafer, the base fiber is light and is not easily damaged or broken.

The photovoltaic fiber according to at least one example embodiment may be manufactured by a roll-to-roll process. For example, if gas-jet electron beam plasma chemical vapor deposition (GJ EBP CVD) equipment, a supercritical deposition apparatus, and the like are used if coating materials on a fiber, the materials may be more uniformly coated on the fiber, and a photovoltaic fiber may be manufactured more inexpensively, efficiently, and easily and with higher productivity by a roll-to-roll process without using a large area deposition apparatus. The equipment may use multiple chambers, and it may coat various kinds of materials on the fiber at a high speed at a low temperature. For example, a photoactive layer material, an electrode material, an insulating material, and the like may be uniformly coated.

Further, if a self-aligned imprint lithography (SAIL) process is used if etching the material coated on a fiber, a photovoltaic fiber may be more efficiently and easily formed because there is no alignment process.

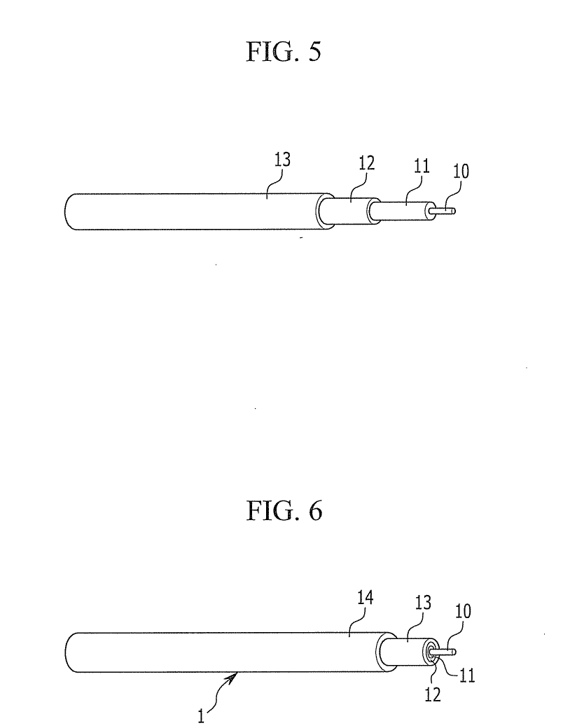

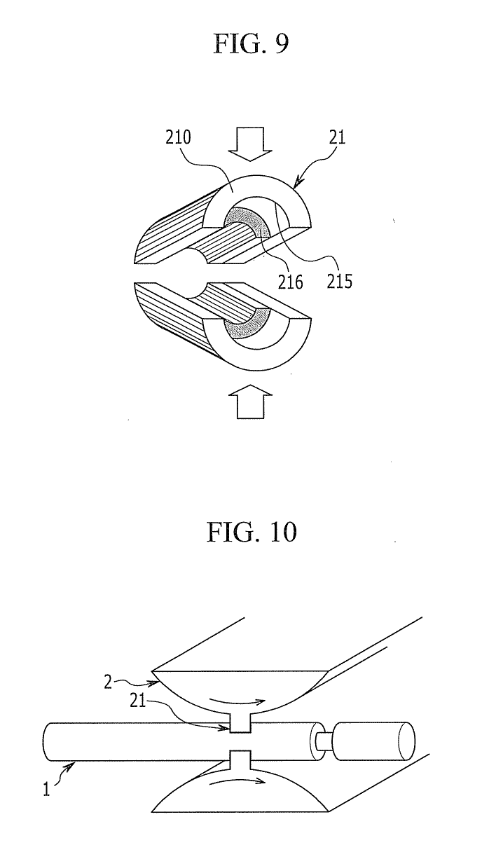

FIG. 1 to FIG. 12 schematically show a process of manufacturing a photovoltaic fiber according to an example embodiment.

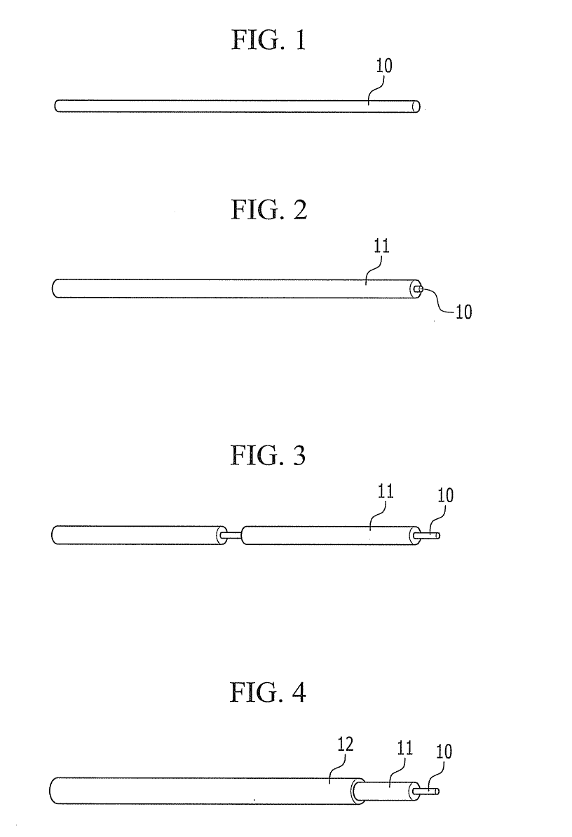

Referring to FIG. 1 and FIG. 2, an insulating material and an electrode material are sequentially coated on a base fiber 10 using GJ EBP CVD equipment, a supercritical deposition apparatus, and the like by a roll-to-roll process to sequentially form an insulating layer (not shown) and a first electrode 11. The first electrode 11 may also be referred to as a core electrode. The process of coating the insulating material may be omitted.

Referring to FIG. 3, the first electrode 11 may be etched by laser scribing and the like to isolate a space between cells, which is referred to as an isolation region. Alternatively, the first electrode 11 may be etched in a SAIL process to be applied later.

Referring to FIG. 4 to FIG. 6, a photovoltaic fiber 1 may include a photoactive layer material, an electrode material, and an protective layer material that may be sequentially coated on the first electrode 11 using GJ EBP CVD equipment, a supercritical deposition apparatus, and the like by a roll-to-roll process to sequentially form a photoactive layer 12, a second electrode 13, and a protective layer 14. A PIN junction or a PN junction may be formed in the photoactive layer 12. The PIN junction may be formed in the order of P, I, and N, or in the order of N, I, and P. The PN junction may be formed in the order of P and N or in the order of N and P. The PIN junction may have a higher efficiency due to good light trapping structural characteristics of the photoactive layer 12. Also, the photoactive layer 12 may be formed of multi-crystalline silicon or nanocrystalline silicon and may have a higher efficiency despite the thin thickness. The second electrode 13 may also referred to as a shell electrode. The protective layer 12 may be formed of a material including an inorganic material such as aluminum oxide (AlOx) and the like, or an organic material such as a polymer material and the like. If the photovoltaic fiber 1 receives light, current is generated in the photoactive layer 12, and the current flows through the first electrode 11 and the second electrode 13. If the protective layer 12 is coated on a reflective material such as an aluminum thin film and the like, the amount of light passing through a photovoltaic battery may decrease, thereby improving photovoltaic efficiency.

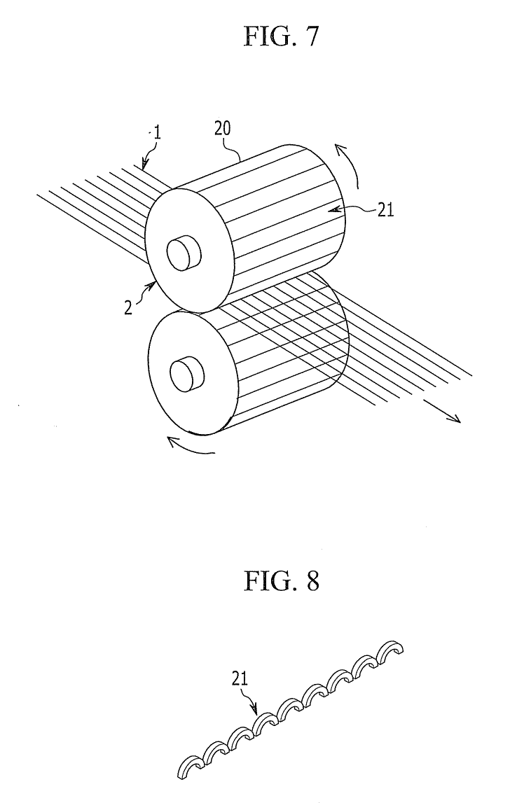

Referring to FIG. 7 to FIG. 12, it can be seen that a SAIL process is undertaken by a roll-to-roll process, and since the roll-to-roll process may be applied to an etching process following a deposition process, a photovoltaic fiber 1 having a required or desired structure may be manufactured with higher productivity.

Referring to FIG. 7, polymer material may be coated on the photovoltaic fiber 1 including a photoactive layer, an electrode, and the like, and the photovoltaic fiber 1 may be passed between rollers 2 (see FIG. 10) disposed or installed in upper and lower directions. If the first electrode 11 is already etched, a plurality of photovoltaic fibers 1 are aligned with reference to the patterned first electrode 11, and then the plurality of photovoltaic fibers 1 may be passed between the rollers 2. For example, the polymer material may include a homo-polymer or copolymer of ethylene vinyl acetate (EVA).

Referring to FIG. 8 to FIG. 10, the roller 2 includes an imprinting unit 21. The imprinting unit 21 may include a body 210, a first protrusion portion 215, and a second protrusion portion 216. If necessary, the imprinting unit may include 3 or more protrusion portions. The imprinting unit 21 positioned between the rollers 2 allows imprinting of a polymer at regular intervals. Further, a plurality of imprinting units 21 may be spaced apart from each other at regular intervals.

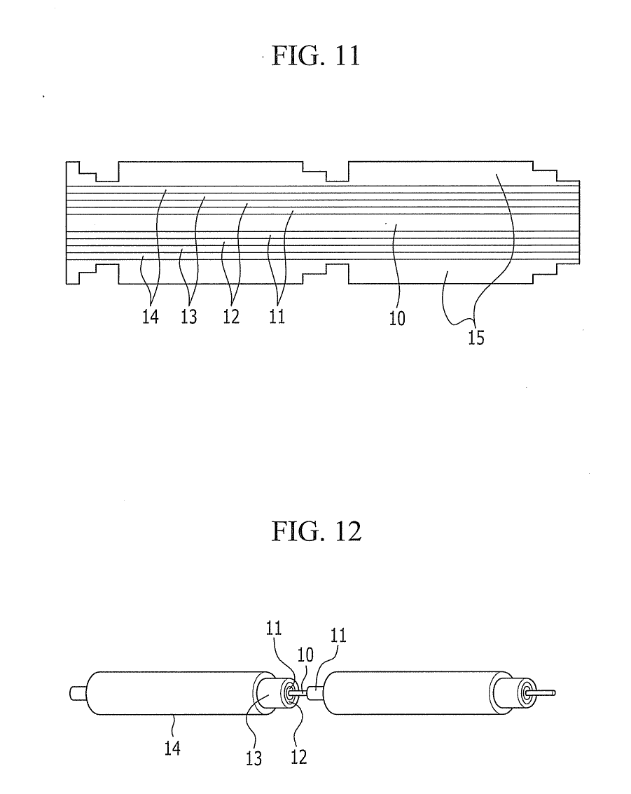

FIG. 11 shows the photovoltaic fiber 1 before etching, and FIG. 12 shows the photovoltaic fiber 1 after etching.

Referring to FIG. 11 and FIG. 12, the thinnest portion of a polymer photoresist 15 is exposed by an ashing and mask etching process through GJ EBP CVD. The base fiber 10 is continuously exposed by an etching process of the main body of the photovoltaic fiber 1, thereby isolating the first electrode 11. The first electrode 11 is then exposed by a mask etching process through an ashing and an etching process of the main body of the photovoltaic fiber 1. Then, the second electrode 13 is exposed by a mask etching process through an ashing and an etching process of the main body of the photovoltaic fiber 1. The etching of the main body of the photovoltaic fiber 1 may be undertaken by wet etching instead of GJ EBP CVD.

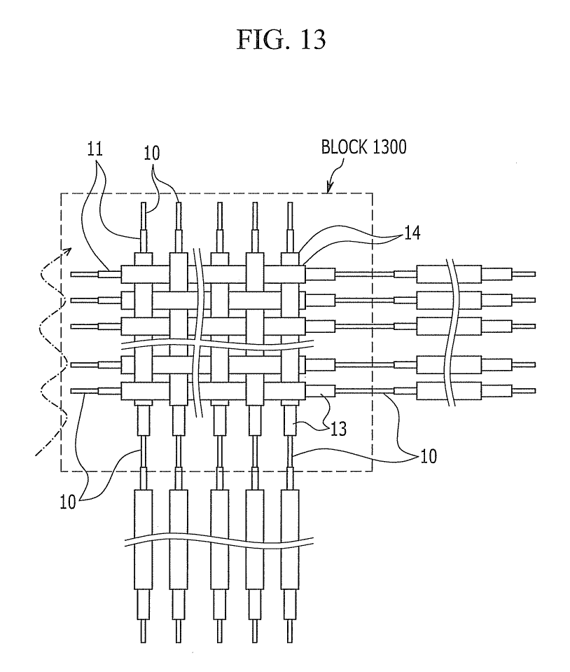

Referring to FIG. 13, if photovoltaic fibers are woven using a weaving machine, a photovoltaic fabric wherein photovoltaic fibers extending in a column direction and a row direction cross each other may be manufactured. In this way, the first electrodes 11, the photoactive layers 12, or the second electrodes 13 of the photovoltaic fibers are aligned with each other. Since resistance increases as the length of the photovoltaic fiber increases, a photovoltaic module may be controlled based on one isolation block BLOCK 1300 with one isolation cell having the shortest length as one side so as to optimize output power. Furthermore, a series connection circuit, a parallel connection circuit, and the like may be constituted using the isolation block BLOCK 1300, and the circuit may be formed by inkjet printing. The photovoltaic module may be manufactured with a larger area.

Specifically, in FIG. 13, photoactive layers 12 or second electrodes 13 are aligned at the bottom side and the right side of the isolation block BLOCK 1300, and first electrodes 11, photoactive layers 12, or second electrodes 13 are aligned at the top side and the left side of the isolation block BLOCK 1300. The exposed length of the first electrode 11, the photoactive layer 12, or the second electrode 13 may be similar to the sum of the diameters of the plurality of photovoltaic fibers 1.

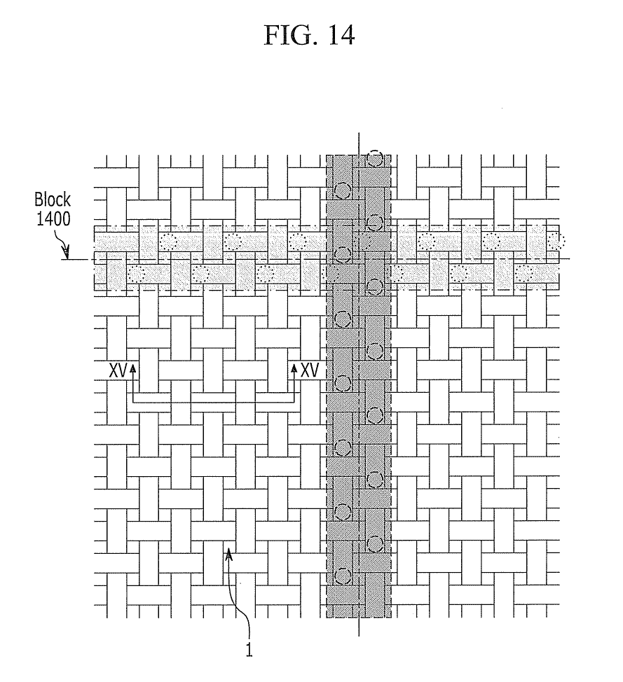

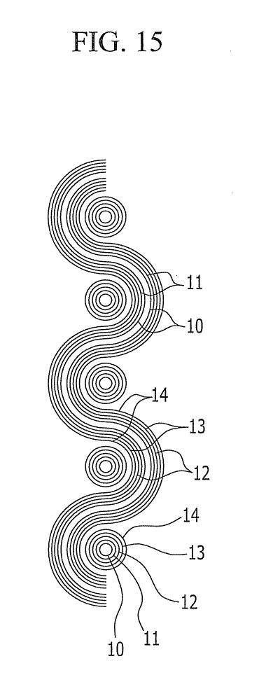

As shown in FIG. 14, a plurality of photovoltaic fibers 1 may be woven to form a photovoltaic fabric. Furthermore, FIG. 14 illustrated an isolation block BLOCK 1400 including the photovoltaic fabric. As shown in FIG. 15, a plurality of woven photovoltaic fibers 1 may have a multi-layered photovoltaic cell structure, whereby light may be more efficiently absorbed thus allowing manufacture of a higher efficiency solar cell. In FIG. 14, a circle indicated by a dotted line indicates a region where the first electrode 11, photoactive layer 12, or the second electrode 13 may contact a connection electrode.

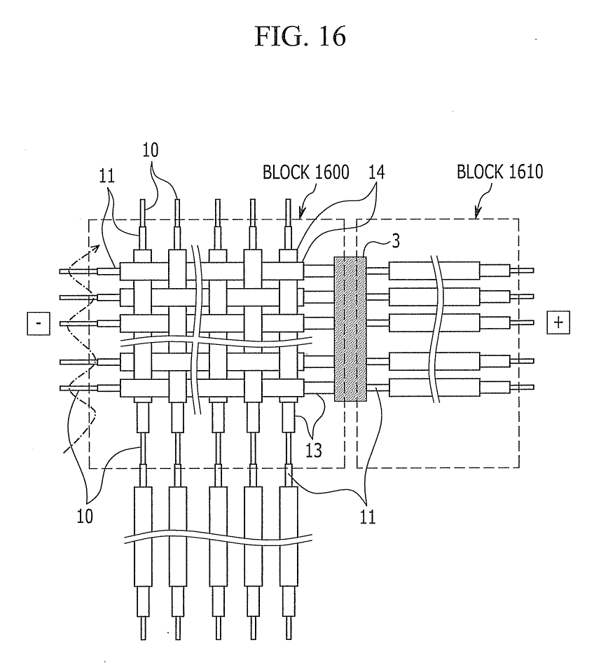

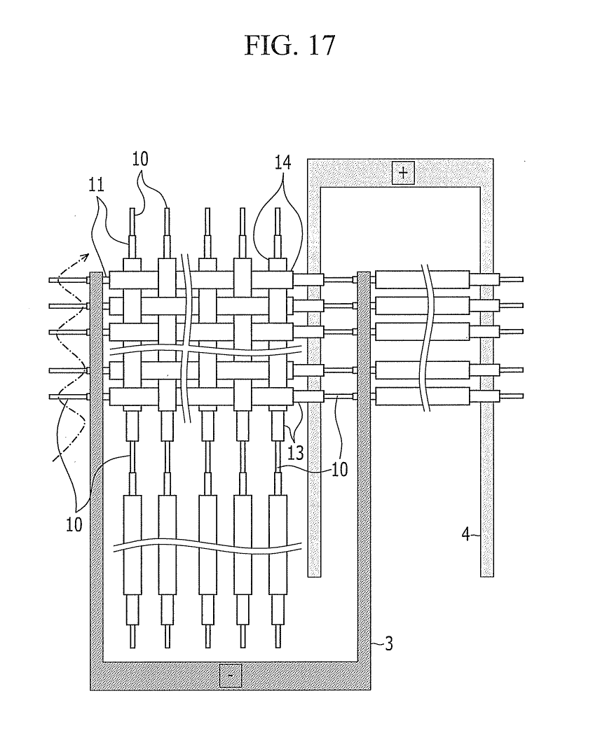

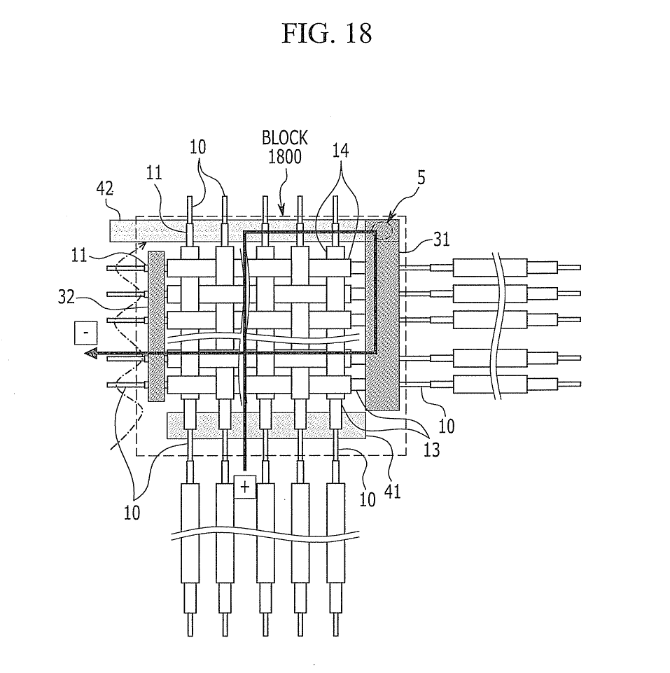

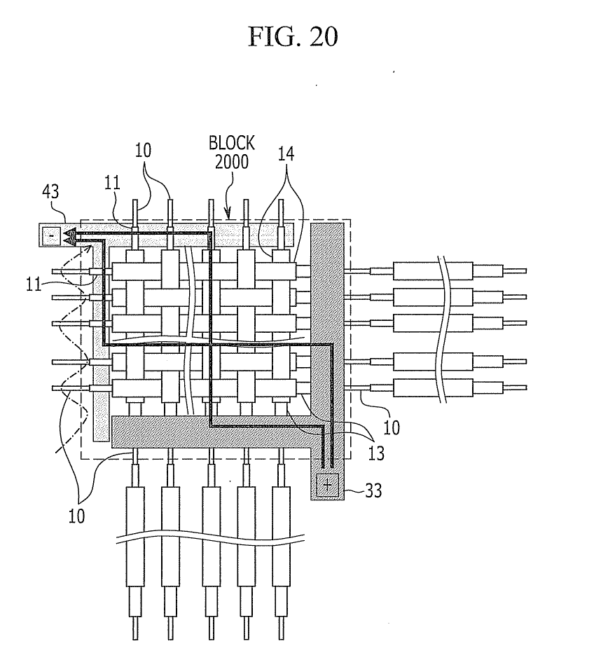

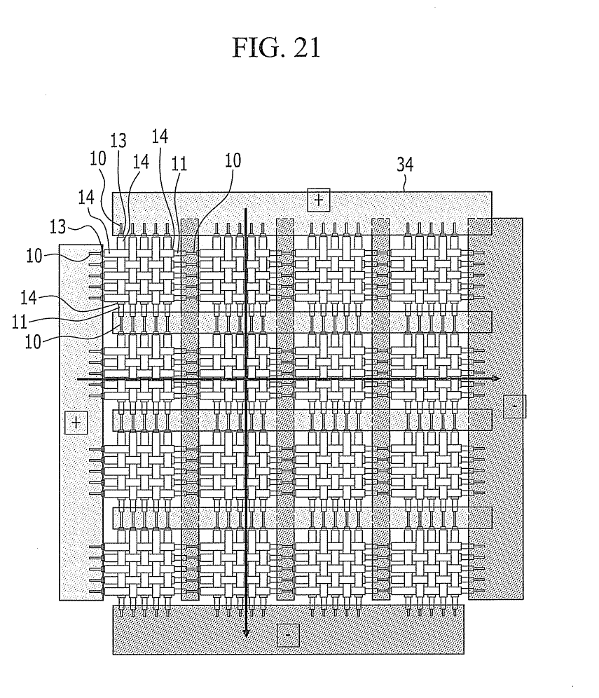

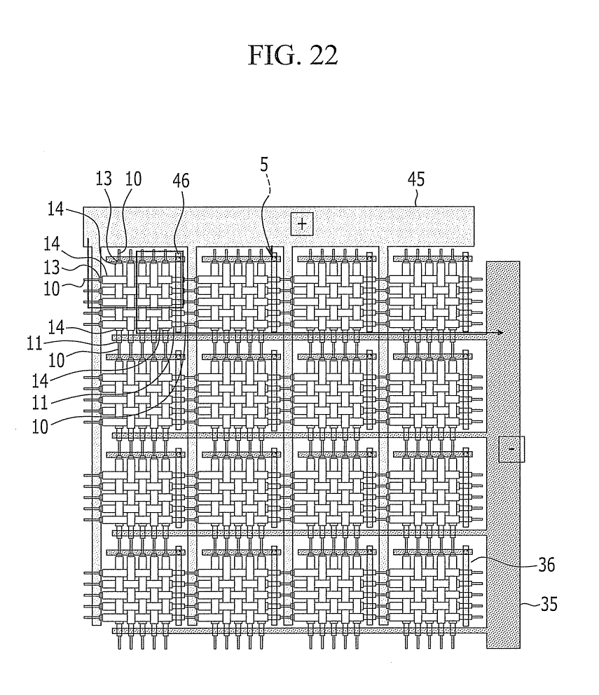

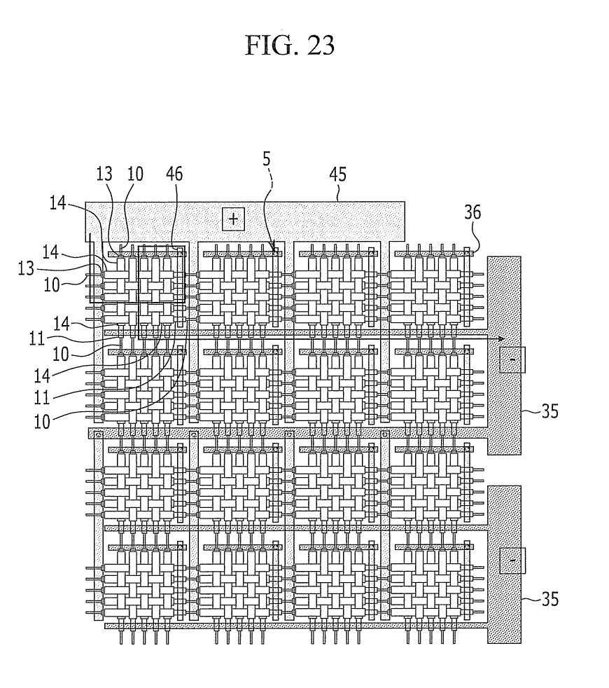

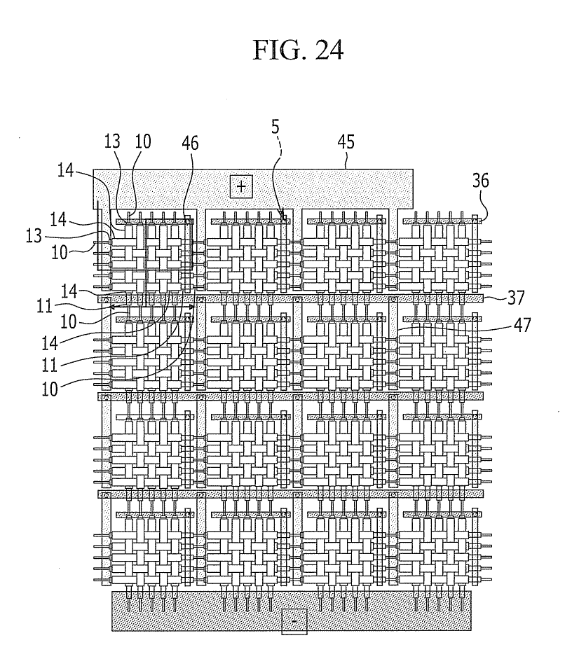

For example, the conductive material may be coated on the plurality of first electrodes 11, the conductive material may be coated on the plurality of photoactive layers 12, or the conductive material may be coated on the plurality of second electrodes 13. The conductive material may be used to connect the plurality of first electrodes 11, the plurality of photoactive layers 12 and the plurality of second electrodes 13. Thereby, as shown in FIG. 16 and FIG. 17, a series connection or a parallel connection between the isolation blocks BLOCK 1600 and BLOCK 1610 may be realized, or as shown in FIG. 18 and FIG. 20, a series connection or a parallel connection inside of the isolation block BLOCK 1800 may be realized. Furthermore, as shown in FIG. 21 to FIG. 24, a photovoltaic module having various connection relationships may be designed by diversely combining the connection relationships.

Referring to FIG. 16, a photovoltaic module wherein two isolation blocks are connected in series is shown. The photoactive layer 12 or the second electrode 13 of one isolation block is connected with the first electrode 11 of another isolation block by a connection electrode 3. The generated current may flow from positive (+) to negative (−). The connection electrode 3 may be formed by various methods such as printing, deposition, spin coating, slit coating, and the like.

Referring to FIG. 17, a photovoltaic module wherein two isolation blocks are connected in parallel is shown. The photoactive layer 12 or the second electrode 13 of one isolation block is connected with the photoactive layer 12 or the second electrode 13 of another isolation block by the connection electrode 3. Further, the first electrode 11 of one isolation block is connected with the first electrode 11 of another isolation block by a connection electrode 4. The generated current may flow from positive (+) to negative (−). In this case, even if one isolation block of the isolation blocks connected in parallel is abnormal, other isolation blocks may be normally operated. The connection electrodes 3 and 4 may be positioned on the front side of the first electrode 11, the photoactive layer 12, or the second electrode 13, or on the rear side thereof. Further, the connection electrodes 3 and 4 may be formed by various methods such as printing, deposition, spin coating, slit coating, and the like.

Referring to FIG. 18, photovoltaic fibers extending in a column direction and photovoltaic fibers extending in a row direction are connected in series in one isolation block BLOCK 1800. For example, the first electrodes 11 of the plurality of photovoltaic fibers extending in a column direction are connected with each other by one connection electrode 42, and the photoactive layers 12 or the second electrodes 13 of the plurality of photovoltaic fibers extending in a column direction are connected with each other by one connection electrode 41. Further, the first electrodes 11 of the plurality of photovoltaic fibers extending in a row direction are connected with each other by one connection electrode 32, and the photoactive layers 12 or the second electrode 13 of the plurality of photovoltaic fibers extending in a row direction are connected with each other by one connection electrode 31. The connection electrodes 31, 32, 41, and 42 may be positioned on the front side of the first electrode 11, the photoactive layer 12, or the second electrode 13, or on the rear side thereof. Further, the connection electrodes 31, 32, 41, and 42 may be formed by various methods such as printing, deposition, spin coating, slit coating, and the like.

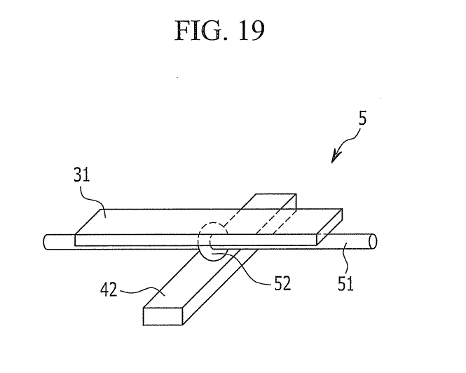

Two connection electrodes 31 and 42 may be connected with each other by a connection member 5. For example, referring to FIG. 19, connection electrodes 31 and 42 are connected with each other by a connection ring 52 fixed to a connection fiber 51 and include a conductive material, whereby photovoltaic fibers extending in a column direction and photovoltaic fibers extending in a row direction may be connected in series. The photovoltaic fibers may also be connected in series by various other methods. Referring to FIG. 18, the generated current may flow from positive (+) to negative (−) along the arrow direction.

Referring to FIG. 20, photovoltaic fibers extending in a column direction and photovoltaic fibers extending in a row direction are connected in parallel in one isolation block BLOCK 2000. For example, the first electrodes 11 of the plurality of photovoltaic fibers extending in a column direction are connected with the first electrodes 11 of the plurality of photovoltaic fibers extending in a row direction by one connection electrode 43. Further, the photoactive layers 12 or the second electrode 14 of the plurality of photovoltaic fibers extending in a column direction are connected with the photoactive layers 12 or the second electrodes 13 of the photovoltaic fibers extending in a row direction by one connection electrode 33. The connection electrodes 33 and 43 may be positioned on the front side of the first electrode 11, the photoactive layer 12, or the second electrode 13, or on the rear side thereof. Further, the connection electrodes 33 and 43 may be formed by various methods such as printing, deposition, spin coating, slit coating, and the like. The generated current may flow from positive (+) to negative (−) along the arrow direction.

Referring to FIG. 21 to FIG. 24, a photovoltaic module combining a series connection or a parallel connection between two isolation blocks and a series connection or a parallel connection in one isolation block is shown. Connection electrodes 34, 35, 36, 37, 44, 45, 46, and 47 may be positioned on the front side of the first electrode 11, the photoactive layer 12, or the second electrode 13, or on the rear side thereof. Further, the connection electrodes 34, 35, 36, 37, 44, 45, 46, and 47 may be connected with each other by a connection member 5, and the connection member 5 may include a connection fiber 51 and a connection ring 52 as shown in FIG. 19. In addition, the connection electrodes 34, 35, 36, 37, 44, 45, 46, and 47 and the connection member 5 may be formed by various methods such as printing, deposition, spin coating, slit coating, and the like.

When manufacturing photovoltaic fibers, different kinds of photoresists may be coated on the photovoltaic fibers extending in a column direction than the photovoltaic fibers extending in a row direction, and then a photolithography process may be applied independently or simultaneously to the photovoltaic fibers extending in the column direction and the photovoltaic fibers extending in the row direction. For example, a negative photoresist may be coated on the photovoltaic fibers extending in a column direction, and a positive photoresist may be coated on the photovoltaic fibers extending in a row direction. If a connection electrode for connecting two isolation blocks is formed using the photolithography process, interference between the photovoltaic fibers extending in a column direction and the photovoltaic fibers extending in a row direction may decrease.

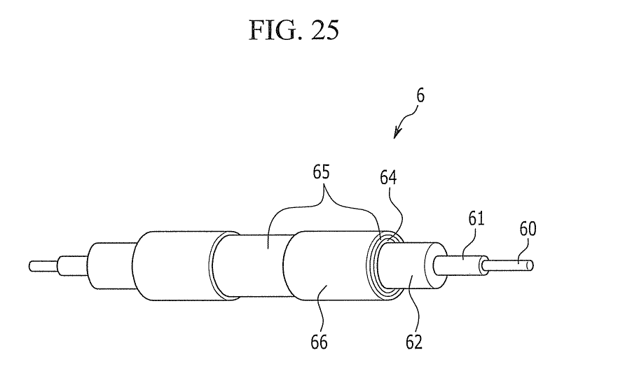

FIG. 25 schematically shows a switching unit according to one example embodiment. For example, a switching fiber 6 may have a top-gate structure. In addition, the switching fiber 6 may have a bottom-gate structure.

The switching fiber 6 may include an insulating layer 61 that may be formed on a base fiber 60. The base fiber 60 may include a glass fiber, a plastic fiber, a polymer fiber, a carbon fiber, and the like. The base fiber 60 may be flexible, may not cause loss of entered light, and may be manufactured with a diameter of several micrometers to dozens of micrometers. The insulating layer 61 may include an organic insulating material, or an inorganic insulating material such as SiOx, SiNx, and the like.

A semiconductor layer 62 may be formed on the insulating layer 61. The semiconductor layer 62 may include a compound semiconductor such as multi-crystalline silicon, nanocrystalline silicon, amorphous silicon, GIZO, and the like, or graphene and the like. The silicon may be hydrogenated silicon.

A gate insulating layer 64 may be formed on the semiconductor layer 62. The gate insulating layer 64 may include an organic insulating material, or an inorganic insulating material such as SiOx, SiNx, and the like.

A gate electrode 65 may be formed on the gate insulating layer 64. The gate electrode 65 may include a metallic material, multi-crystalline silicon, and the like.

An interlayer insulating layer 66 may be formed on the gate electrode 65. The interlayer insulating layer 66 may include an organic insulating material, or an inorganic insulating material such as SiOx, SiNx, and the like.

When forming the switching fiber 6, a roll-to-roll process using multiple chambers may be applied as the process for foaming a photovoltaic fiber. The coating process may be performed with GJ EBP CVD equipment, a supercritical deposition apparatus, and the like, and a patterning process may be performed by a SAIL process. Thereby, the switching fiber 6 may be uniformly coated on the base fiber, and may be manufactured more inexpensively, efficiently, and easily, with a higher productivity, without using a large area deposition apparatus.

A source electrode and a drain electrode may define the semiconductor layer 62 or an ohmic contact layer (not shown) by using an ion shower apparatus, a Schottky barrier junction, implantation, and the like. Further, a lightly doped drain (LDD) region may define the semiconductor layer 62 or the ohmic contact layer through a spacer process.

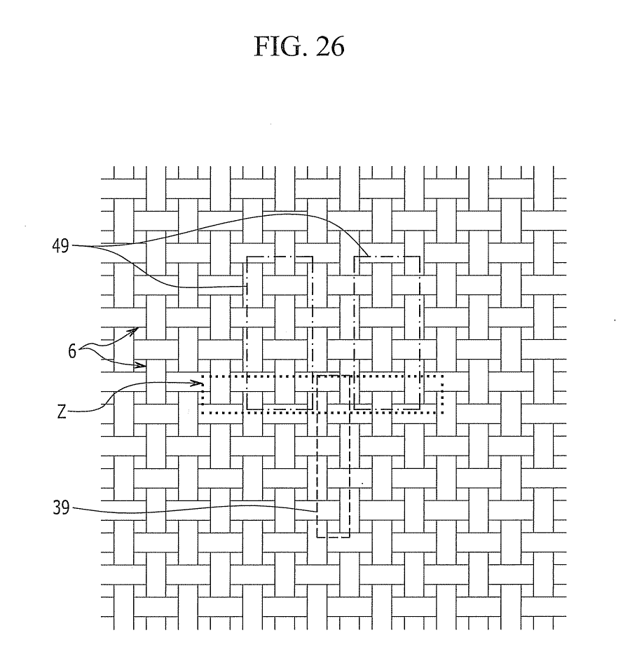

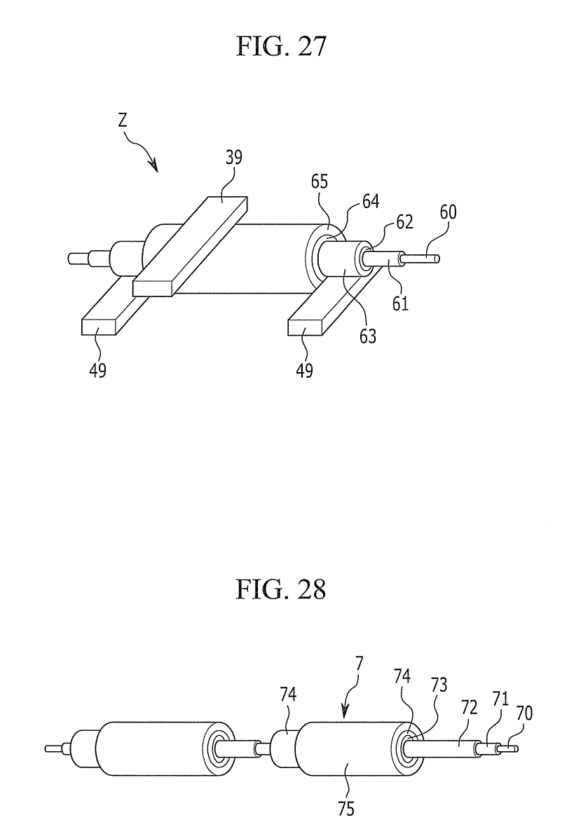

Referring to FIG. 26 and FIG. 27, switching fibers 6 extending in a column direction and switching fibers 6 extending in a row direction crossing each other may be woven with a weaving machine. In addition, switching fibers 6 extending in a column direction and typical fibers extending in a row direction may be woven, and typical fibers extending in a column direction and switching fibers 6 extending in a row direction may be woven. Further, between the plurality of switching fibers 6 extending in one direction, at least one typical fiber extending in the same direction may be positioned.

At least one of a gate electrode line 39, a source electrode line 49, and a drain electrode line 49 may be positioned on the top side of the switching fiber 6, or on the bottom side thereof. Further, at least one of the gate electrode line 39, source electrode line 49, and drain electrode line 49 may be formed by inkjet printing, and it may be simultaneously formed by a process for defining the source electrode and the drain electrode or a SAIL process.

FIG. 28 schematically shows a storage unit according to one example embodiment. For example, a capacitor fiber 7 may be formed according to the shape of the fiber.

The capacitor fiber 7 may include an insulating layer 71 formed on a base fiber 70. The base fiber 70 may include a glass fiber, a plastic fiber, a polymer fiber, a carbon fiber, and the like. The base fibers may be flexible, may not cause loss of entered light, and may be manufactured with a diameter of several micrometers to dozens of micrometers. The insulating layer 71 may include an organic insulating material, or an inorganic insulating material such as SiOx, SiNx, and the like. The insulating layer 71 may be omitted.

A first capacitor electrode 72 may be formed on the base fiber 70. The first capacitor electrode 72 may include a metallic material, multi-crystalline silicon, and the like.

A capacitor insulating layer 73 may be foamed on the first capacitor electrode 72. The insulating layer 73 may include an organic insulating material such as a ceramic material, a polymer, and the like, or inorganic insulating material and the like.

A second capacitor electrode 74 may be formed on the capacitor insulating layer 73, and the second capacitor electrode 74 may include a metallic material, multi-crystalline silicon, and the like.

An interlayer insulating layer 75 may be formed on the second capacitor electrode 74. The interlayer insulating layer 75 may include an organic insulating material, or an inorganic insulating material such as SiOx, SiNx, and the like.

When forming the capacitor fiber 7, a roll-to-roll process using multiple chambers may be applied as the process for forming a photovoltaic fiber. A coating process may be performed with GJ EBP CVD equipment, a supercritical deposition apparatus, and the like, and a patterning process may be performed by a SAIL process. Thereby, the capacitor fiber 7 may be uniformly coated on the fiber, and it may be manufactured more inexpensively, efficiently, and easily, and with a higher productivity, without using a large area deposition apparatus.

FIG. 13 to FIG. 24 and the explanations relating to the weaving of the photovoltaic fiber 1 may also be applied to the capacitor fiber 7. For example, the capacitor fibers 7 may be woven by the same method as the weaving of the photovoltaic fibers 1, and may have the same kind of isolation block and the same kind of connection relationship. The electric power output through the photovoltaic fiber 1 may be stored in the capacitor fiber 7.

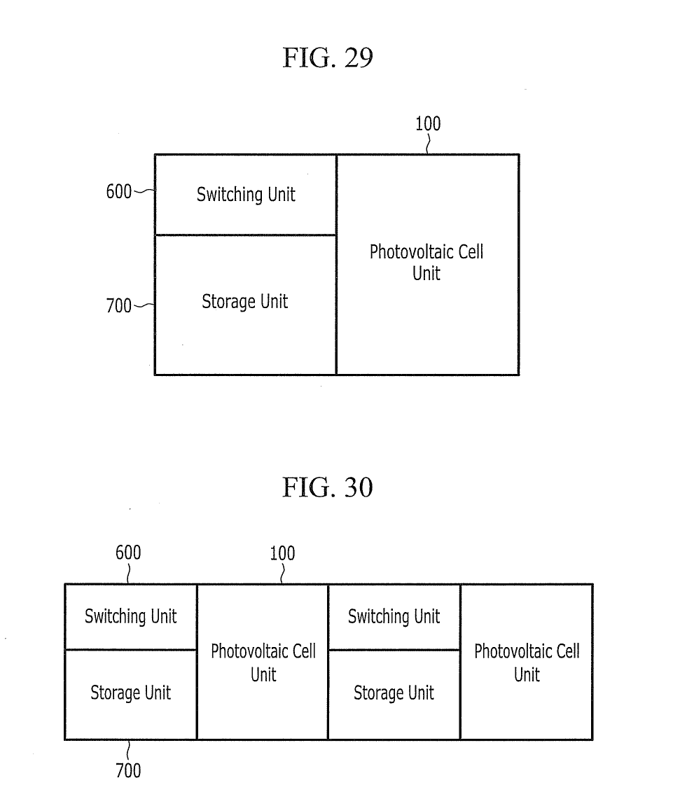

FIG. 29 is a block diagram of the photovoltaic cell module according to one embodiment. The photovoltaic cell module has a monolithic textile structure, and it may include at least one of a photovoltaic cell unit 100, a storage unit 700, and a switching unit 600. A conductive fiber may be used instead of the switching unit 600.

The photovoltaic cell unit 100 converts light energy into electrical energy, and the photovoltaic cell unit 100 may include woven photovoltaic fibers 1. The storage unit 700 stores converted electrical energy, and the storage unit may include at least one of woven capacitor fibers 7, a capacitor, and a battery. Further, the capacitor may be a super capacitor. The switching unit 600 controls at least one of the converted electrical energy and charged electrical energy, and the switching unit 600 may include at least one of a switching fiber 6 and a thin film transistor.

In the photovoltaic cell module shown in FIG. 29, at least one of the photovoltaic cell unit 100, the storage unit 700, and the switching unit 600 may be selectively vertically stacked and positioned on a different plane.

FIG. 30 is a block diagram of the photovoltaic cell module according to another example embodiment. In the photovoltaic cell module, at least one of the photovoltaic cell unit 100, the storage unit 700, and the switching unit 600 may be selectively arranged on one plane.

The photovoltaic fiber may form a wearable woven cloth, and the photovoltaic cell module including woven photovoltaic fibers may maintain an appropriate temperature regardless of seasons. Further, the photovoltaic fiber may be used as a power supply of wearable mobile electronics. In addition, the photovoltaic fiber and the photovoltaic cell module using the same may be applied to a sail of a ship, an aerospace vehicle, and the like. Further, the photovoltaic cell module may be embedded in a material constituting a case for electronics.

While this disclosure has been described in connection with what is presently considered to be practical exemplary embodiments, it is to be understood that at least one example embodiment is not limited to the disclosed embodiments, but, on the contrary, is intended to cover various modifications and equivalent arrangements included within the spirit and scope of the appended claims.

What is claimed is:

1. A photovoltaic fiber comprising:
a first electrode surrounding a base fiber;
a photoactive layer surrounding the first electrode and having a PIN junction positioned in a radial direction; and
a second electrode surrounding the photoactive layer.

2. The photovoltaic fiber of claim 1, wherein the photoactive layer includes silicon.

3. The photovoltaic fiber of claim 2, wherein the photoactive layer includes at least one of a multi-crystalline silicon and a nanocrystalline silicon.

4. The photovoltaic fiber of claim 1, further comprising:
a protective layer surrounding the second electrode.

5. The photovoltaic fiber of claim 4, wherein the protective layer includes a reflective material.

6. The photovoltaic fiber of claim 4, wherein the protective layer includes a polymer material.

7. The photovoltaic fiber of claim 1, wherein the photovoltaic fiber includes an isolation region, and the base fiber is exposed in the isolation region.

8. The photovoltaic fiber of claim 7, wherein at least one of the first electrode and the second electrode is exposed in the isolation region.

9. A photovoltaic fabric including woven photovoltaic fibers, the woven photovoltaic fibers comprising:
a first electrode surrounding a base fiber;
a photoactive layer surrounding the first electrode and having a PIN junction positioned in a radial direction; and
a second electrode surrounding the photoactive layer.

10. The photovoltaic fabric of claim 9, wherein the photoactive layer includes silicon.

11. The photovoltaic fabric of claim 10, wherein the photoactive layer includes at least one of a multi-crystalline silicon and a nanocrystalline silicon.

12. The photovoltaic fabric of claim 9, wherein the photovoltaic fabric includes a plurality of isolation blocks, an isolation region being positioned at the circumference of an isolation block, and the base fiber is exposed in the isolation region,
and the isolation block includes a first photovoltaic fiber extending in a first direction and a second photovoltaic fiber extending in a second direction, the first direction and the second direction being different from each other.

13. The photovoltaic fabric of claim 12, wherein the plurality of isolation blocks are electrically connected with each other in at least one of series and parallel.

14. The photovoltaic fabric of claim 13, wherein a first end of the first photovoltaic fiber and a second end of the second photovoltaic fiber are connected with each other.

15. A photovoltaic cell module comprising:
a photovoltaic cell device comprising woven photovoltaic fibers, the photovoltaic cell device being configured to convert light energy into electrical energy, the photovoltaic cell device including,
a plurality of isolation blocks,
an isolation region positioned at the circumference of an isolation block, and
a base fiber is exposed in the isolation region, and the isolation block including a first photovoltaic fiber extending in a first direction and a second photovoltaic fiber extending in a second direction, the first direction and the second direction being different from each other.

16. The photovoltaic cell module of claim 15, wherein each of the first photovoltaic fiber and the second photovoltaic fiber comprise:
a first electrode surrounding a base fiber;
a photoactive layer surrounding the first electrode, and having a PIN junction positioned in a radial direction; and
a second electrode surrounding the photoactive layer.

17. The photoactive cell module of claim 15, wherein the plurality of isolation blocks are electrically connected with each other in at least one of series or parallel.

18. The photoactive cell module of claim 17, wherein a first end of the first photovoltaic fiber and a second end of the second photovoltaic fiber are connected with each other.

19. The photoactive cell module of claim 17, wherein the plurality of isolation blocks are connected with each other through a connection electrode.

20. The photoactive cell module of claim 15, further comprising:
a storage unit configured to store the electrical energy.

21. The photoactive cell module of claim 20, wherein the storage unit includes woven capacitor fibers, the woven capacitor fibers including the first photovoltaic fiber and the second photovoltaic fiber.

22. The photoactive cell module of claim 21, wherein the capacitor fibers comprise:
a first capacitor electrode surrounding a base fiber;
a capacitor insulating layer surrounding the first capacitor electrode; and
a second capacitor electrode surrounding the capacitor insulating layer.

23. The photoactive cell module of claim 15, further comprising:
a switching unit configured to control the electrical energy.

24. The photoactive cell module of claim 23, wherein the switching unit includes woven switching fibers, the woven switching fibers including the first photovoltaic fiber and the second photovoltaic fiber.

25. The photoactive cell module of claim 24, wherein the woven switching fibers comprise:
a semiconductor layer positioned on a base fiber;
a gate electrode positioned on the base fiber; and
a gate insulating layer positioned between the semiconductor layer and the gate electrode.

26. A method of manufacturing a photovoltaic fiber, comprising:
forming a first electrode on a base fiber by a roll-to-roll process;
forming a photoactive layer on the first electrode by a roll-to-roll process; and
forming a second electrode on the photoactive layer by a roll-to-roll process.

27. The method of claim 26, wherein the first electrode, the photoactive layer, and the second electrode are formed using at least one of gas jet electron beam plasma chemical vapor deposition (CVD) equipment and a supercritical deposition apparatus.

28. The method of claim 27, wherein the first electrode, the photoactive layer, and the second electrode are formed by self-aligned imprint lithography.

29. The method of claim 26, further comprising:
coating a polymer material on the second electrode, and
imprinting the polymer material by a roller, the roller including an imprinting unit.

30. The method of claim 26, wherein the roll-to-roll process uses multiple chambers.

31. The method of claim 26, wherein the first electrode surrounds the base fiber, the photoactive layer surrounds the first electrode, and the second electrode surrounds the photoactive layer.
